(19) United States
(12) Patent Application Publication
(10) Pub. No.: US 2007/0287290 A1
(43) Pub. Date: Dec. 13, 2007

(54) MANUFACTURING METHOD FOR NON-ACTIVE ELECTRICALLY STRUCTURES OF AN INTEGRATED ELECTRONIC CIRCUIT FORMED ON A SEMICONDUCTOR SUBSTRATE AND CORRESPONDING ELECTRONIC CIRCUIT

(75) Inventors: Alfonso Maurelli, Sulbiate (IT); Daniela Peschiaroli, Milano (IT); Fausto Piazza, Agrate Brianza (IT); Carlo Vigiani, Novara (IT); Paola Zabberoni, Monza (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 11/754,494

(22) Filed: May 29, 2007

(30) Foreign Application Priority Data
May 31, 2006 (EP) 06425371.9

(51) Int. Cl. H01L 21/302; H01L 21/31

(52) U.S. Cl. 438/691; 438/926; 438/770; 257/E23.179

(57) ABSTRACT

Electrically non-active structures are formed for an electronic circuit to make uniform a surface above a semiconductor substrate. The electronic circuit includes first electrically active structures comprising conductive elements of a first height projecting from the semiconductor substrate, and second electrically active structures comprising conductive elements of a second height projecting from the semiconductor substrate. The first height is different from the second height. The electrically non-active structures are formed by identifying, among the electrically non-active structures, a first group of electrically non-active structures formed within areas that substantially extend for a radius around each electrical component belonging to the second electrically active structures. The method further includes identifying, among the electrically non-active structures, a second group of electrically non-active structures not belonging to the first group of electrically non-active structures. The electrically non-active structures belonging to the first group of electrically non-active structures are formed with elements projecting from the semiconductor substrate having a height equal to the second height. The electrically non-active structures belonging to the second group of electrically non-active structures are formed with elements projecting from the semiconductor substrate having a height equal to the first height.

### FIELD OF THE INVENTION

The present invention relates to a method for manufacturing electrically non-active structures of an integrated electronic circuit formed on a semiconductor substrate. The invention particularly, but not exclusively, relates to an electronic circuit comprising memory cells of the Flash type and low voltage circuitry associated therewith. The following description is made with reference to this field of application by way of illustration only.

### BACKGROUND OF THE INVENTION

In the design of electronic circuits integrated on a semiconductor substrate, formed in submicron CMOS technologies, the introduction of electrically non-active service structures referred to as dummy structures, is becoming more necessary. These structures are used to improve the definition, during the manufacturing process, of the electrically active components of an integrated circuit.

The dummy structures, provided in the realization steps of integrated circuits judged critical for a determined technology, allow an increase in the local density of electrically active structures which need to be integrated on a same semiconductor substrate. The dummy structures, in fact, formed by elements projecting from the semiconductor substrate, for example with polygonal sections, significantly reduce the differences of size and of shape between electrically active structures placed close to very dense circuit structure areas and those placed inside such areas.

Moreover, removal techniques for layers with tools sensitive to the morphology of the circuit structures, such as the CMP (Chemical Mechanical Polishing), further makes it necessary for the introduction of dummy structures since the presence of these dummy structures also helps to reduce, as much as possible, the height differences between dense areas of electrically active circuits.

Generally, the arrangement or layout of these dummy structures between the electrically active components of an integrated circuit occurs in an automatic way. This is based on the indications provided by the technology used, which uses software instruments normally used by the experts in the field.

U.S. Pat. No. 7,001,800 titled “Manufacturing Method For Non-Active Electrically Structures In Order To Optimize The Definition Of Active Electrically Structures In An Electronic Circuit Integrated On A Semiconductor Substrate And Corresponding Circuit”, describes a method for the formation of dummy structures inside an integrated electronic circuit CI comprising a matrix M of non-volatile memory cells and an associated circuitry C, as shown in FIG. 1. This method provides the formation of dummy structures in two different photolithographic steps. In the first step, the dummy structures D1 as shown in FIG. 2, adjacent to the matrix M and to the circuitry C, are defined. In the second step, the dummy structures D2 as shown in FIG. 3, not adjacent to the matrix M and to the circuitry C are defined. It is also known that the dummy structures D1, D2 as shown in FIGS. 2 and 3 are formed by the same layers forming the memory cells of the matrix M. The '800 patent is assigned to the current assignee of the present invention, and is incorporated herein by reference in its entirety.

Known non-volatile memory matrixes M of the Flash type integrated on a semiconductor comprise a plurality of non-volatile memory cells organized in a matrix, i.e., the cells are organized in rows called word lines WL, and columns called bit lines BL.

Each single non-volatile memory cell comprises a MOS transistor wherein the gate electrode, placed above the channel region, is floating. That is, it has a continuous high impedance towards all the other terminals of the same cell and of the circuit wherein the cell is inserted. The floating gate electrode is generally formed by a first polysilicon layer.

The cell also comprises a second electrode, called a control gate, which is capacitively coupled to the floating gate electrode through an intermediate dielectric layer, called an interpoly. The second electrode is driven through suitable control voltages. The control electrode is generally formed by a second polysilicon layer.

Conventionally, the matrix of memory cells is associated with control circuitry comprising conventional MOS transistors. Each MOS transistor having a source region and a drain region separated by a channel region. A gate electrode is then formed on the channel region and is insulated therefrom by a gate oxide layer. This gate electrode is generally formed by a polysilicon layer.

Then, as shown in FIG. 4, each dummy structure D1, D2 is formed by a stacked structure which comprises a first gate oxide layer OG, a first polysilicon layer P1, an ONO layer and a second polysilicon layer P2 formed on a semiconductor substrate S. The stacked structure is then etched to form an element projecting from the semiconductor substrate S above a respective active area A delimited by field oxide regions OX formed on semiconductor substrate S. The stacked structure is then formed by the same layers with which the memory cells of the matrix M are formed. Therefore, the topology of the integrated circuit CI next to the matrix M is rather regular, and allows a correct definition of the gate electrodes of the memory cells.

The approach proposed in the cited document, although allowing to make the areas exposed by the photolithographic masks used to define the structures of the circuitry and of the matrix as much identical as possible, and thus allowing good definition at the process level, also of the areas relative to the area occupied by the memory, shows some drawbacks.

In fact, as shown in FIG. 5, this method for generating and thus forming these dummy structures D1 introduces heavy microloading effects. That is, it produces regions of different thickness, during the definition step of the polysilicon gate electrodes of the MOS transistors of circuitry C, especially when the sizes of the gate electrodes are sub-micrometric, for example smaller then or equal to 0.13 μm for low voltage transistors LV.

These microloading effects are exactly due to the fact that the dummy structures D1 near the active structures of circuitry C are defined with a higher number of layers with respect to those which are used for the structures of circuitry C. That is, these structures are defined by elements projecting from the semiconductor substrate S of different heights. This introduces a sort of step G between the region wherein the LV transistors are formed and the region with dummy structures. This causes undesired effects during the masking and etching step of the gate itself due to a local thinning of a photoresist layer PH which is formed between the regions wherein the LV transistors are formed and the regions with dummy structures. This jeopardizes the correct definition of the photoresist layer PH during the successive photolithographic steps.

### SUMMARY OF THE INVENTION

In view of the foregoing background, an object of the present invention is to provide a method for manufacturing dummy structures, having such characteristics as to allow safeguarding of a correct definition of the matrix areas and to eliminate the microloading effects still limiting the integrated circuits formed according to the prior art.

This and other objects, advantages and features in accordance with the present invention are provided by identifying dummy structures automatically generated in the layout of an integrated circuit formed on a semiconductor substrate which comprises first electrically active structures which comprise electric components provided with conductive elements of a first height projecting from the semiconductor substrate, and second electrically active structures which comprise electric components provided with conductive elements of a second height projecting from the semiconductor substrate.

The method may further comprise identifying a first group of dummy structures adjacent to the second group of electrically active structures. The dummy structures belonging to the first group of dummy structures may be provided with elements projecting from the semiconductor substrate having a height equal to the second height. The dummy structures which do not belong to the first group of dummy structures may instead be provided with elements projecting from the semiconductor substrate having a height equal to the first height.

Advantageously, the dummy structures belonging to the first group of dummy structures may be defined and formed in the same process steps in which the second electrically active structures are defined and formed, while the remaining dummy structures may be defined and formed in the same process steps in which the first electrically active structures are defined and formed.

More particularly, a method for manufacturing electrically non-active structures for an electronic circuit integrated on a semiconductor substrate comprising first electrically active structures comprising conductive elements of a first height projecting from the semiconductor substrate, and second electrically active structures comprising conductive elements of a second height projecting from the semiconductor substrate, with the first height being different from the second height, is provided. The method may comprise inserting the electrically non-active structures in the electronic circuit to make uniform a surface above the semiconductor substrate.

The inserting may comprise identifying, among the electrically non-active structures, a first group of electrically non-active structures formed within areas that substantially extend for a radius around each electrical component belonging to the second electrically active structures. The method may further comprise identifying, among the electrically non-active structures, a second group of electrically non-active structures not belonging to the first group of electrically non-active structures. The electrically non-active structures belonging to the first group of electrically non-active structures may be formed with elements projecting from the semiconductor substrate having a height equal to the second height. The electrically non-active structures belonging to the second group of electrically non-active structures may be formed with elements projecting from the semiconductor substrate having a height equal to the first height. The elements belonging to the first and second groups of electrically non-active structures may be formed by respective photolithographic steps.

Another aspect of the invention is directed to an electronic circuit comprising a semiconductor substrate, first electrically active structures in the semiconductor substrate and comprising conductive elements of a first height projecting therefrom, and second electrically active structures in the semiconductor substrate and comprising conductive elements of a second height projecting therefrom.

Electrically non-active structures may be formed to make uniform a surface above the semiconductor substrate. The electrically non-active structures may comprise a first group of electrically non-active structures within areas that substantially extends for a radius around each electrical component belonging to the second electrically active structures, and comprising elements projecting from the semiconductor substrate having a height equal to the second height. The electrically non-active structures may further comprise a second group of electrically non-active structures comprising electrically non-active structures not belonging to the first group of electrically non-active structures, and comprising elements projecting from the semiconductor substrate having a height equal to the first height.

### BRIEF DESCRIPTION OF THE DRAWINGS

The characteristics and the advantages of the method according to the invention will be apparent from the following description of an embodiment thereof given by way of indicative and non-limiting examples with reference to the annexed drawings. In the drawings:

FIG. 1 shows an example of layout of an integrated circuit, at the active area level, comprising a portion of a flash non-volatile memory matrix and a circuitry portion according to the prior art;

FIG. 2 shows the layout of FIG. 1 wherein the dummy structures adjacent to the flash non-volatile memory matrix and to the circuitry have been identified;

FIG. 3 shows the layout of FIG. 1 wherein the dummy structures not adjacent to the flash non-volatile memory matrix and to the circuitry have been identified;

FIG. 4 shows a vertical section of a dummy structure formed according to the prior art;

FIG. 5 shows a vertical section of a portion of the integrated circuit of FIG. 1 wherein dummy structures of the known type have been described according to the prior art;

FIG. 6 shows an example of layout of an integrated circuit comprising a portion of flash non-volatile memory matrix and circuitry portions wherein two different areas have been identified wherein, through two distinct process steps, two different groups of dummy structures are to be defined according to the present invention;

FIGS. 7 and 8 show vertical sections of a portion of the integrated circuit of FIG. 6 wherein dummy structures adjacent to memory cells during some steps of the method according to the invention have been formed;

FIGS. 9 and 10 show vertical sections of a portion of the integrated circuit of FIG. 6 wherein dummy structures adjacent to transistors of the circuitry during some steps of the method according the invention have been formed; and

FIGS. 11 and 12 show two photolithographic masks wherein geometric shapes are etched for forming gate electrodes of electrically active structures, and elements projecting from the substrate of electrically non-active structures which are comprised in the integrated electronic circuit 1 of FIG. 6.

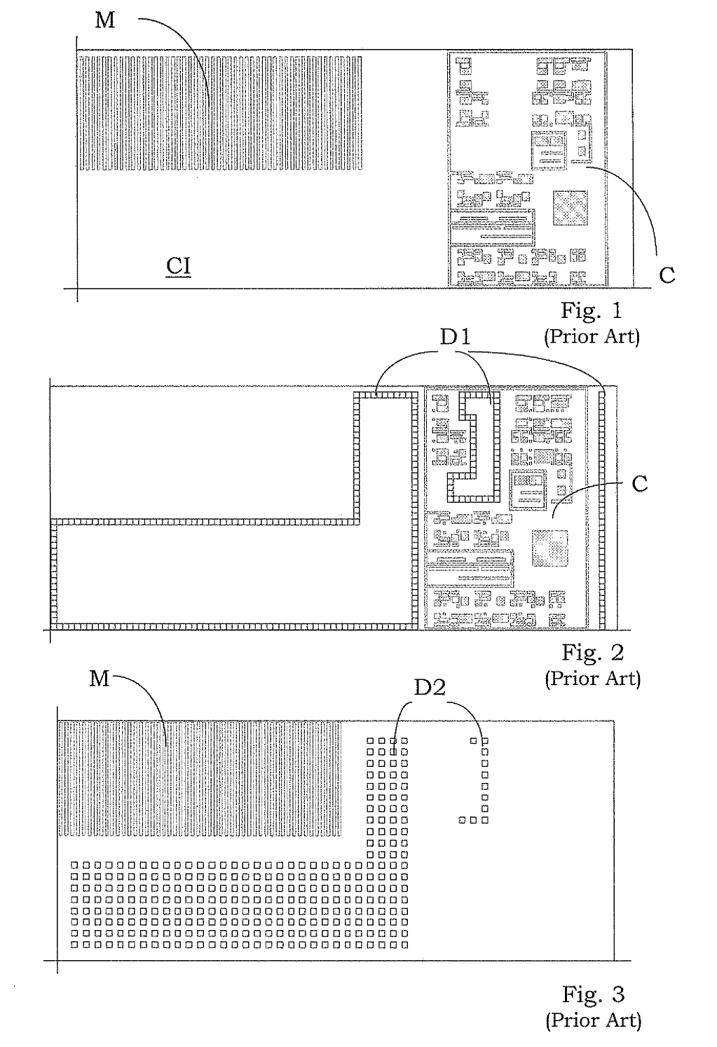

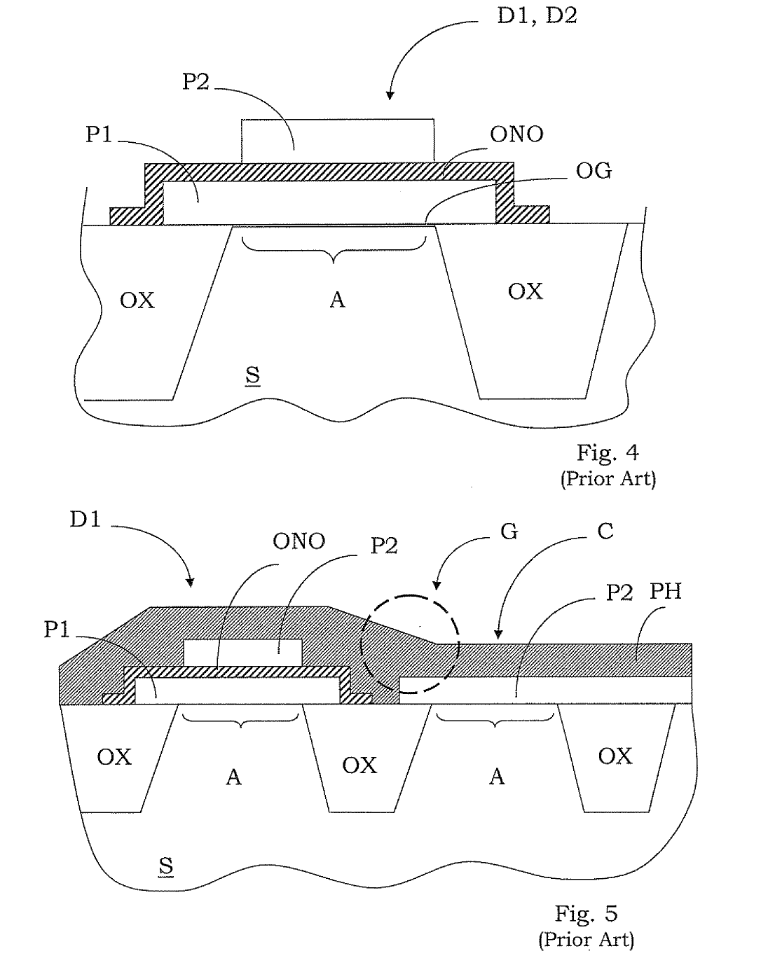

### DETAILED DESCRIPTION OF THE PREFERRED EMBODIMENTS

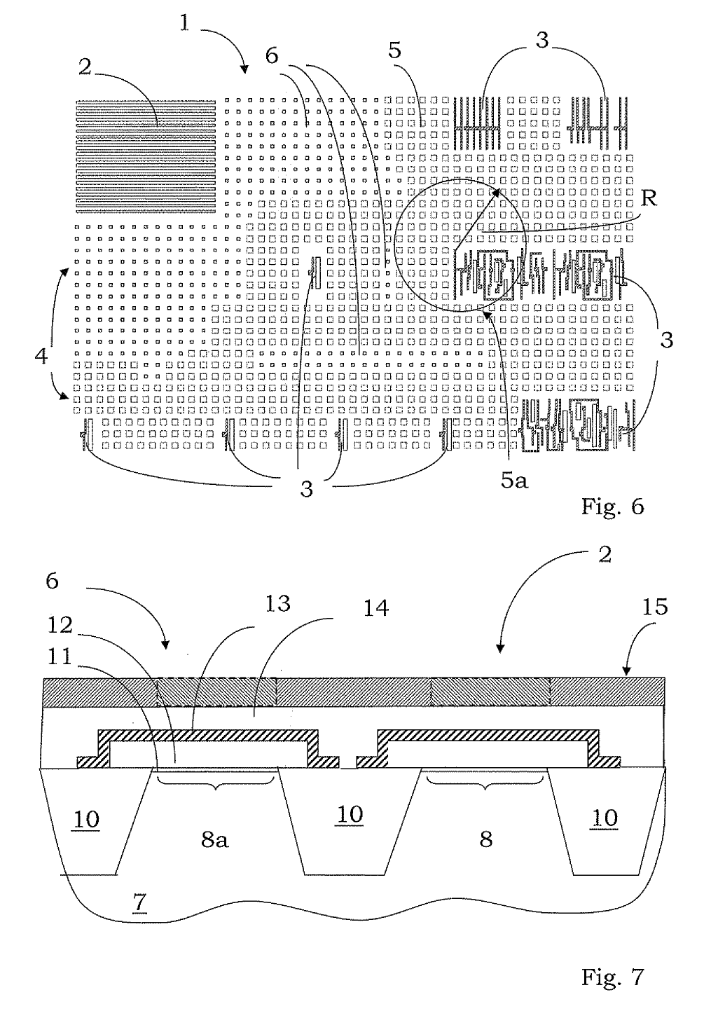

With reference to FIGS. 6 to 10, a method is described for manufacturing electrically non-active structures of an integrated electronic circuit formed on a semiconductor substrate. The process steps described hereafter do not form a complete process flow for the manufacturing of integrated circuit. The present invention can be put into practice together with the manufacturing techniques of integrated circuits currently used in the field, and in the description only those process steps being commonly used and necessary for the comprehension of the present invention are included.

The figures showing transversal sections of portions of an integrated circuit during the manufacturing are not drawn to scale, but they are instead drawn so as to show the important characteristics of the invention.

In particular, with reference to FIG. 6, the composition is shown of two photolithographic masks wherein the geometric shapes are etched for forming gate electrodes of circuit structures which are comprised in an integrated electronic circuit 1. In particular, this integrated electronic circuit 1 comprises first electrically active structures 2, which comprise electric components having conductor elements 16 projecting from a semiconductor substrate 7 of a first height H1, for example, memory cells of a matrix of memory cells of the FLASH type, and second electrically active structures 3 which comprise electric components having conductor elements 20 projecting from a semiconductor substrate 7 of a second height H2, for example, transistors of the MOS type, diodes, resistances or capacitors.

For a correct implementation of the method according to the invention, nothing forbids that, among the second electrically active structures 3, electrical components comprise conductor elements projecting from the semiconductor substrate 7 of a height different from the second height H2.

As it has already been said with reference to the prior art, electrically non-active or dummy structures 4 are introduced into the integrated electronic circuit 1. The identification step of the positions in which these electrically non-active structures 4 will be formed inside the integrated electronic circuit 1 usually occurs through an analysis of the electrically active structures present in the integrated electronic circuit 1, and the successive calculation (layer by layer) of the density of the electrically active structures present on the semiconductor substrate 7. In case this density is lower than that established by the technology, the automatic insertion of these dummy structures 4 is provided inside the empty portions of the integrated electronic circuit 1 so as to reach a desired density.

In this method, a first group 5 of dummy structures is then defined which is formed by the dummy structures in areas 5a which substantially extend for a radius R around each electric component of the second electrically active structures 3, and a second group 6 of dummy structures including dummy structures not belonging to the first group 5 of dummy structures.

Advantageously, the first group 5 of dummy structures is defined, at the preparation of the masks, simultaneously with the second electrically active structures 3, while the second group of dummy structures 6 is defined simultaneously with the first electrically active structures 2.

Advantageously, each dummy structure belonging to the first group S of dummy structures is formed at least by the same number of conductive layers forming the second electrically active structures 3, for example a single polysilicon layer. This is while each dummy structure belonging to the second group 6 of dummy structures is formed at least by the same number of conductive layers forming the first electrically active structures 2, for example two polysilicon layers.

In other words, each dummy structure belonging to the first group 5 of dummy structures is formed by an element 20a projecting from the substrate 7 having a height equal to the second height H2, while each dummy structure belonging to the second group 6 of dummy structures is formed by an element 16a projecting from the substrate 7 having a height equal to the first height H1.

Advantageously, the value of the radius R can be chosen so that each component belonging to the second electrically active structures 3 is surrounded by a sufficient number of dummy structures belonging to the first group 5 of dummy structures, so as to efficiently reduce the microloading effects in the portions of integrated electronic circuit 1 being arranged between the second electrically active structures 3 and the first group 5 of dummy structures.

Advantageously, the radius R can be chosen so that the number of dummy structures belonging to the second group 6 of dummy structures is high enough so that the amount of area exposed by the photolithographic mask used to form this second group 6 of dummy structures, when these dummy structures are formed together with the first electrically active structures 2, is not excessively low.

In fact, each dummy structure belonging to the first group 5 of dummy structure may be formed at least by the same number of conductive layers forming the second electrically active structures 3. The surface of the integrated electronic circuit 1 around these second electrically active structures 3 is rather uniform.

In a preferred embodiment, all the dummy structures comprised in the areas 5a belong to the first group 5 of dummy structures.

An electronic circuit 1 is then defined for being integrated on a semiconductor substrate 7, and comprises first electrically active structures 2 which comprise electrical components provided with conductive elements 16 of a first height H1 projecting from the semiconductor substrate 7, and second electrically active structures 3 which comprise electrical components provided with conductive elements 20 of a second height H2 projecting from the semiconductor substrate 7, as well as electrically non-active structures 4 to superficially uniform the electronic circuit.

The electrically non-active areas 4 comprise first and second groups 5, 6 of electrically non-active structures. The first group 5 of electrically non-active structures comprise in areas 5a which substantially extend for a predetermined radius R around each electric component belonging to the second electrically active structures 3, elements 20a projecting from the substrate 7 having a height equal to the second height H2. The second group 6 of electrically non-active structures comprise electrically non-active structures not belonging to the first group 5 of electrically non-active structures, and are provided with elements 16a projecting from the substrate 7 having a height equal to the first height H1.

To more clearly illustrate the advantages of the method according to the invention clearer, an embodiment thereof is now described, as a non-limiting example. In particular, a method is described for manufacturing an integrated electronic circuit 1 on a semiconductor substrate 7 comprising a matrix 2 of non-volatile memory cells of the Flash type, and an associated circuitry comprising a plurality of MOS transistors 3, as well as dummy structures 4 to superficially make uniform the electronic circuit 1.

In particular, on a semiconductor substrate 7, memory cells 2, active areas 9 and transistors 3 are formed.

The conventional process steps to form these active areas provide forming, in cascade, a silicon oxide layer and a silicon nitride layer on the semiconductor substrate 7, and selectively removing the silicon nitride and silicon oxide layers by a photolithographic technique which provides the use of a first photolithographic mask for forming active areas 8 wherein the memory cells 2 are formed. A part of the semiconductor substrate is formed by using the same first photolithographic mask forming trenches which separate different regions of the nitride layer that have not been removed.

The process steps here described for forming the active areas 8 are then repeated to manufacture the active areas 9 of the transistors 3, using a second photolithographic mask.

The process goes on in a known way with the steps of oxidizing the surface of the exposed semiconductor substrate 7 and filling in the trenches in the semiconductor substrate 7 with a field oxide layer 10, and planarizing the surface by a CMP technique (chemical mechanical polishing) for removing the dielectric layer formed above the silicon nitride layer. The silicon nitride layer and the underlying oxide layer are removed for uncovering the surface of the active areas 8 and the active areas 9.

Moreover, so as to increase the amount of semiconductor substrate 7 to be removed for manufacturing the active areas 8, 9, active areas are defined for the dummy structures 4 as well.

These dummy structures 4 are divided into a first group 5 of dummy structures which is formed by dummy structures in areas 5a which substantially extend for a radius R around each transistors 3, and a second group 6 of dummy structures comprising dummy structures not belonging to the first group 5 of dummy structures.

In a first particularly advantageous embodiment of the invention, in the same process steps in which the active areas 9 of the transistors 3 are formed, active areas 9a of the first group 5 of dummy structures are formed. In other words, the second photolithographic mask provides a plurality of openings to form the active areas 9 of the transistors 3, and a plurality of openings to form the active areas 9a of the first group 5 of dummy structures.

Moreover, the active areas 8a of the second group 5 of dummy structures are formed in the same process steps in which the active areas 8 of the memory cells 2 are formed. Therefore, the first photolithographic mask provides a plurality of openings to form the active areas 8 of the memory cells 2, and a plurality of openings to form the active areas 8a of the second group 6 of dummy structures.

In an embodiment of the method according to the invention, the sizes of the active areas 8a of the second group 6 of dummy structures are smaller than the sizes of the active areas 9a of the first group 5 of dummy structures.

This embodiment is particularly advantageous when the percentage of dummy structures of the second group 6 of dummy structures, i.e., those defined at the first mask relative to the memory cells 2 of the matrix, is rather low and could introduce problems in the etching step of the semiconductor substrate 7 caused by a small exposed area of the first mask.

The method provides formation, above the active areas 8, 8a a first multilayer structure comprising a first dielectric layer 11 such as an active oxide, a first conductive layer 12 such as polysilicon, a second dielectric layer 13 such as an interpoly oxide, and a second conductive layer 14 such as polysilicon.

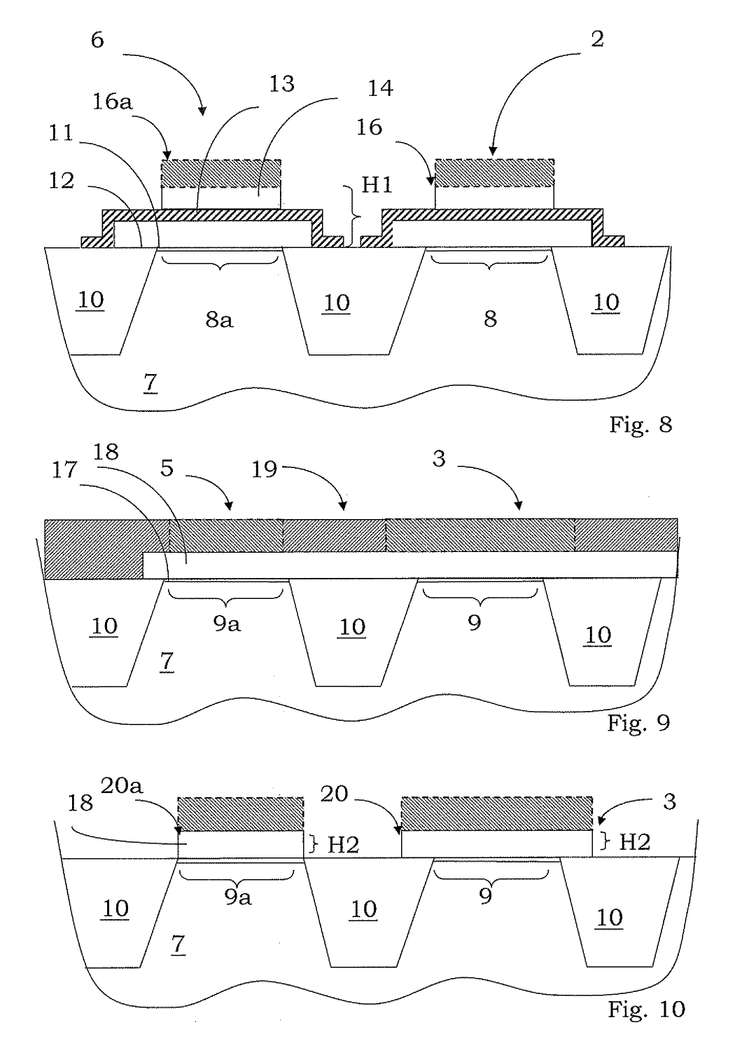

By using conventional photolithographic techniques which provide the use of at least one third the photolithographic mask 15 formed by a resist layer also indicated with reference number 15, in the first multilayer structure gate electrodes 16 of the memory cells 2 are defined. In particular, as shown in FIGS. 7 and 8, through the third mask 15, the second conductive layer 14 is etched.

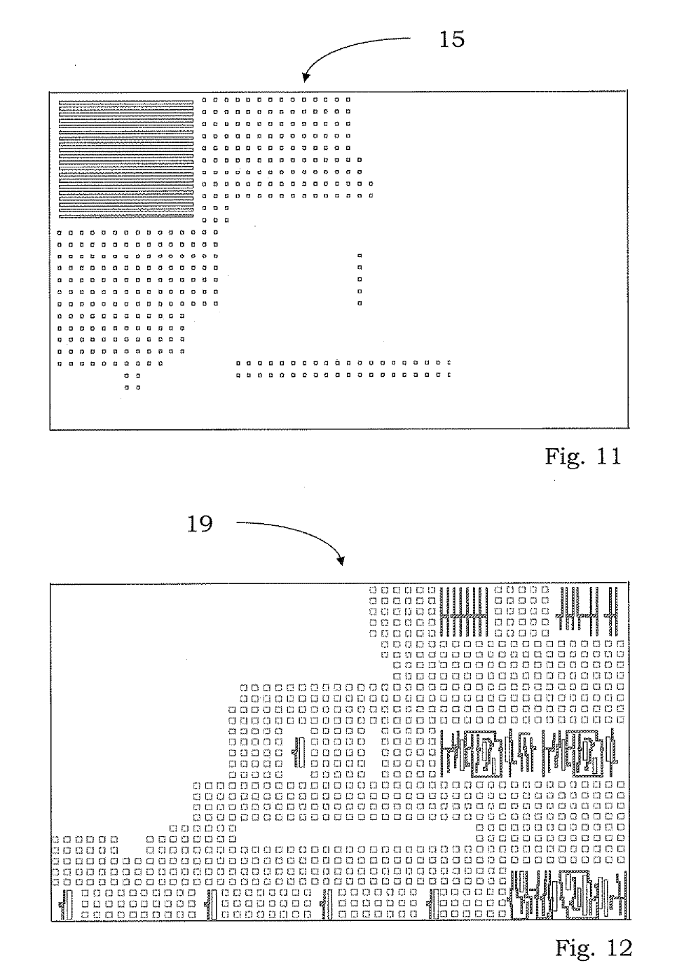

Advantageously, together with the gate electrodes 16 of the memory cells 2 having a first height H1, elements 16a projecting from the semiconductor substrate 7 having a height equal to the first height H1 belonging to the second group 6 of dummy structures are defined. In this case, the layout of the third photolithographic mask 15 is shown in FIG. 11.

Advantageously, the elements 16a with height H1 are formed in the same process steps in which the gate electrodes 16 are formed. Therefore, the elements 16a and the gate electrodes 16 are formed by the same number of layers.

The method provides formation, above the active areas 9, 9a of the first group 5 of dummy structures and of the transistors 3, a second multilayer structure comprising a third dielectric layer 17 such as an active oxide also known as a tunnel oxide, and a third conductive layer 18 such as polysilicon.

Advantageously, the third conductive layer 18 is simultaneously formed with the second conductive layer 12 or with the first conductive layer 14 of the cells of the matrix.

By using conventional photolithographic techniques which provide the use of at least one fourth the photolithographic mask 19, formed by a resist layer also indicated with reference number 19 in the second multilayer structure gate electrodes 20 of the transistors 3 are defined, as shown in FIGS. 9 and 10.

Advantageously, together with the gate electrodes 20 of the transistors 3 having a second height H2, elements 20a projecting from the semiconductor substrate 7 having height equal to the second height H2 belonging to the first group 5 of dummy structures are defined. In this case, the layout of the fourth photolithographic mask 19 is shown in FIG. 12.

In particular, the elements 20a of height H2 are formed in the same process steps in which the gate electrodes 20 are formed. Therefore, the elements 20a and the gate electrodes 20 are formed by the same number of layers.

The elements 16a of height H1 and the elements 20a of height H2 are then defined by to distinct steps. It can be noted that in the areas of the integrated circuit 1 near the transistors 3 the conformation of the photoresist layer 19 is more planar with respect to the conformation of the photoresist layer PH which was deposited on known structures, as shown in FIG. 5. This reduces the microloading effects caused by the different photoresist local thickness.

Although in the description reference has been made to a process for the simultaneous formation of a memory matrix and a circuitry region in the same integrated circuit formed on a semiconductor substrate, the method according to the invention can be equally applied to electrically active structures integrated in an integrated circuit comprising conductive elements projecting from the semiconductor substrate with different height H1 and H2.

In conclusion, the method according to the invention allows definition at the mask manufacturing level, and a consequential realization on a semiconductor substrate 7, of dummy structures 4 so as to define most of these structures 6 simultaneously with the definition of the matrix 2 active area. However, this is done without jeopardizing the correct realization of the electrodes 20 of the circuitry due to the microloading effects.

1-14. (canceled)

15. A method for manufacturing electrically non-active structures for an electronic circuit integrated on a semiconductor substrate comprising first electrically active structures comprising conductive elements of a first height projecting from the semiconductor substrate, and second electrically active structures comprising conductive elements of a second height projecting from the semiconductor substrate, with the first height being different from the second height, the method comprising:
inserting the electrically non-active structures in the electronic circuit to make uniform a surface above the semiconductor substrate, the inserting comprising
identifying, among the electrically non-active structures, a first group of electrically non-active structures formed within areas that substantially extend for a radius around each electrical component belonging to the second electrically active structures,
identifying, among the electrically non-active structures, a second group of electrically non-active structures not belonging to the first group of electrically non-active structures,
forming the electrically non-active structures belonging to the first group of electrically non-active structures with elements projecting from the semiconductor substrate having a height equal to the second height,
forming the electrically non-active structures belonging to the second group of electrically non-active structures with elements projecting from the semiconductor substrate having a height equal to the first height, and
the elements belonging to the first and second groups of electrically non-active structures being formed by respective photolithographic steps.

16. A method for manufacturing electrically non-active structures according to claim 15, wherein the first group of electrically non-active structures is formed together with the second electrically active structures.

17. A method for manufacturing electrically non-active structures according to claim 15, wherein the second group of electrically non-active structures is formed together with the first electrically active structures.

18. A method for manufacturing electrically non-active structures according to claim 17, wherein each element belonging to the first group of electrically non-active structures is formed by at least a same number of conductive layers forming the conductive elements belonging to the second electrically active structures.

19. A method for manufacturing electrically non-active structures according to claim 18, wherein each element belonging to the second group of electrically non-active structures is formed by at least a same number of conductive layers forming the elements belonging to the first electrically active structures.

20. A method for manufacturing electrically non-active structures according to claim 18, wherein the electronic circuit comprises a matrix of non-volatile memory cells comprising floating gate transistors, and wherein the first electrically active structures comprise the floating gate transistors of the matrix of non-volatile memory cells.

21. A method for manufacturing electrically non-active structures according to claim 17, wherein the electronic circuit comprises circuitry associated with a matrix of non-volatile memory cells, the circuitry comprising MOS transistors, and wherein the second electrically active structures comprise the MOS transistors of the circuitry associated with the matrix of non-volatile memory cells.

22. A method for manufacturing electrically non-active structures according to claim 15, wherein the active areas in which the elements belonging to the second group of electrically non-active structures are formed is smaller in size as compared to the active areas in which the elements belonging to the first group of electrically non-active structures are formed.

23. A method for manufacturing an electronic circuit comprising:
forming first electrically active structures in a semiconductor substrate, the first electrically active structures comprising conductive elements of a first height projecting from the semiconductor substrate;
forming second electrically active structures in the semiconductor substrate comprising conductive elements of a second height projecting from the semiconductor substrate, with the first height being different from the second height; and
inserting electrically non-active structures to make uniform a surface above the semiconductor substrate, the inserting comprising
identifying, among the electrically non-active structures, a first group of electrically non-active structures formed within areas that substantially extend for a radius around each electrical component belonging to the second electrically active structures,
identifying, among the electrically non-active structures, a second group of electrically non-active structures not belonging to the first group of electrically non-active structures,
forming the electrically non-active structures belonging to the first group of electrically non-active structures with elements projecting from the semiconductor substrate having a height equal to the second height,
forming the electrically non-active structures belonging to the second group of electrically non-active structures with elements projecting from the semiconductor substrate having a height equal to the first height, and
the elements belonging to the first and second groups of electrically non-active structures being formed by respective photolithographic steps.

24. A method for manufacturing electrically non-active structures according to claim 23, wherein the first group of electrically non-active structures is formed together with the second electrically active structures.

25. A method for manufacturing electrically non-active structures according to claim 23, wherein the second group of electrically non-active structures is formed together with the first electrically active structures.

26. A method for manufacturing electrically non-active structures according to claim 25, wherein each element belonging to the first group of electrically non-active structures is formed by at least a same number of conductive layers forming the conductive elements belonging to the second electrically active structures.

27. A method for manufacturing electrically non-active structures according to claim 26, wherein each element belonging to the second group of electrically non-active structures is formed by at least a same number of conductive layers forming the elements belonging to the first electrically active structures.

28. A method for manufacturing electrically non-active structures according to claim 26, wherein the electronic circuit comprises a matrix of non-volatile memory cells comprising floating gate transistors, and wherein the first electrically active structures comprise the floating gate transistors of the matrix of non-volatile memory cells.

29. A method for manufacturing electrically non-active structures according to claim 25, wherein the electronic circuit comprises circuitry associated with a matrix of non-volatile memory cells, the circuitry comprising MOS transistors, and wherein the second electrically active structures comprise the MOS transistors of the circuitry associated with the matrix of non-volatile memory cells.

30. A method for manufacturing electrically non-active structures according to claim 23, wherein the active areas in which the elements belonging to the second group of electrically non-active structures are formed is smaller in size as compared to the active areas in which the elements belonging to the first group of electrically non-active structures are formed.

31. An electronic circuit comprising:
a semiconductor substrate;
first electrically active structures in said semiconductor substrate and comprising conductive elements of a first height projecting therefrom;
second electrically active structures in said semiconductor substrate and comprising conductive elements of a second height projecting therefrom; and
electrically non-active structures to make uniform a surface above the semiconductor substrate, and comprising
a first group of electrically non-active structures formed within areas that substantially extends for a radius around each electrical component belonging to the second electrically active structures, and comprising elements projecting from said semiconductor substrate having a height equal to the second height, and
a second group of electrically non-active structures comprising electrically non-active structures not belonging to the first group of electrically non-active structures, and comprising elements projecting from said semiconductor substrate having a height equal to the first height.

32. An electronic circuit according to claim 31, wherein each element belonging to said first group of electrically non-active structures comprises a same number of conductive layers forming said conductive elements belonging to said second electrically active structures.

33. An electronic circuit according to claim 31, wherein each element belonging to said second group of electrically non-active structures comprises at least a same number of conductive layers forming said conductive elements belonging to said first electrically active structures.

34. An electronic circuit according to claim 31, wherein said first electrically active structures comprise non-volatile memory cells.

35. An electronic circuit according to claim 31, wherein said second electrically active structures comprise MOS transistors belonging to circuitry associated with a matrix of non-volatile memory cells.

36. An electronic circuit according to claim 31, wherein said first electrically active structures are spaced close to each other, and wherein said second electrically active structures are spaced further apart from each other.
